(19) United States
(12) Patent Application Publication
(10) Pub. No.: US 2011/0291193 A1
(43) Pub. Date: Dec. 1, 2011

(54) HIGH DENSITY BUTTED JUNCTION CMOS INVERTER, AND MAKING AND LAYOUT OF SAME

(75) Inventors: Andres Bryant, Burlington, VT (US); Josephine B. Chang, Mahopac, NY (US); Jeffrey W. Sleight, Ridgefield, CT (US)

(73) Assignee: International Business Machines Corporation, Armonk, NY (US)

(21) Appl. No.: 12/788,362

(22) Filed: May 27, 2010

(51) Int. Cl. H01L 27/12; H01L 21/86

(52) U.S. Cl. 257/350; 438/154; 257/E27.112; 257/E21.704

(57) ABSTRACT

A high density, asymmetric, butted junction CMOS inverter, formed on an SOI substrate, may include: an asymmetric p-FET that includes a halo implant on only a source side of the p-FET; an asymmetric n-FET that includes a halo implant on only a source side of the n-FET; and a butted junction comprising an area of said SOI substrate where a drain region of the asymmetric n-FET and a drain region of the asymmetric p-FET are in direct physical contact. Asymmetric halo implants may be formed by a sequential process of covering a first FET of the CMOS inverter with an ion-absorbing structure and applying angled ion radiation to only the source side of the second FET, removing the ion-absorbing structure, covering the first FET with a second ion-absorbing structure, and applying angled ion radiation to only the source side of the second FET. A layout display of CMOS integrated circuit may require one ground rule for the high density, asymmetric butted junction CMOS inverter and another ground rule for other CMOS circuits.

### BACKGROUND

1. Field of the Invention

The present invention relates to a high density, butted junction, complementary metal oxide semiconductor (CMOS) inverter, the making of the high density, butted junction CMOS inverter, and ground rules for the layout of the high density, butted junction CMOS inverter in a CMOS integrated circuit including circuits other than the high density, butted junction CMOS inverter. In particular, the high density, butted junction CMOS inverter of the invention comprises two asymmetric field effect transistors (FETs). In particular, the ground rule for the layout of the high density, butted junction CMOS inverter allows for smaller gate-to-gate spacing of the two asymmetric FETs, when compared to the gate-to-gate spacing of FETs used in circuits other than the CMOS inverter of the invention.

2. Description of the Related Art

To decrease size and cost of integrated circuits, semiconductor devices are scaled down and subject to shrinking design ground rules to maintain manufacturability. However, as a semiconductor device is scaled down, changes are required in the device's structure to maintain performance enhancements from one generation of scaled devices to the next. Additionally, new design ground rules are required to accommodate the layout of the smaller structures and to incorporate these smaller structures into various circuits.

Scaling of a semiconductor device, such as a FET, includes not only a size reduction of gate length and width, but also requires a scaling of the substrate dopant concentration. The performance characteristics of a FET are affected by the substrate dopant concentration and channel length of the active region. For a given dopant concentration, as the channel length is scaled to smaller dimensions, the FET becomes more susceptible to short channel effects such as punch through. “Punch through” is characterized by a greater tendency for current to flow between the source and drain irrespective of the gate control voltage. When punch through occurs, the FET conducts current regardless of the control voltage applied to the gate.

One method of preventing punch through is to implant halo regions of a conductivity type opposite that of the source/drain (S/D) regions of the FET in the active region of the substrate at the channel edges and bottoms of the S/D regions. As shown in FIG. 1, an FET 100 is formed on a silicon-on-insulator (SOI) substrate comprising: a substrate; an insulator layer, for example, a buried oxide layer; and a top semiconductor layer that includes shallow trench isolation (STI) regions and a semiconductor region. The semiconductor region includes a channel region 112 located beneath a gate stack including a gate 122 and source/drain (S/D) regions on either side of the channel region 112. Halo regions 128 may be formed by a symmetrically angled ion implant process on both the source side and drain side of the channel region 112.

It is also possible to prevent punch through by an asymmetrical halo ion implant process. In particular, asymmetrical halo implantation on only the source side of the FET enhances performance in comparison to symmetrical halo implantation of both the source and drain sides of the FET. With symmetrical halo implantation, the device's performance is compromised by the increased junction capacitance and peak electric field caused by the drain side's halo implant.

Complementary metal oxide semiconductor (CMOS) technology is currently the dominant technology for the manufacture of microprocessors, microcontrollers, static random access memory (SRAM) and other digital circuits. The word “complementary” refers to the fact that a typical CMOS digital circuit uses complementary pairs of hole-type (positive) and electron-type (negative) FETs, i.e., p-FETs and n-FETs, respectively. CMOS technology offers low static power consumption and high noise immunity, when compared to other digital technologies.

CMOS manufacturing processes are characterized by their technology node, where a technology node is defined as half the distance between identical features in an array, i.e., the half pitch. For example, the 45 nanometer (45 nm) technology node corresponds to a CMOS memory cell having a half pitch of 45 nm. Further down scaling of CMOS processes anticipates a 22 nm technology node in the near future.

In an SOI CMOS device, an adjacent p-FET and n-FET are subject to current leakage between the complementary pair of transistors and to the unwanted phenomenon of latch-up. For CMOS technology nodes of 250 nm and smaller, adjacent complementary transistors are generally electrically isolated from one another by shallow trench isolation (STI), which also has the benefit of preventing latch-up. FIG. 1 also shows shallow trench isolation (STI) regions surrounding the FET.

A commonly used digital circuit in CMOS devices is a CMOS inverter. For example, one configuration of a single CMOS SRAM cell, which stores a single bit of information, comprises six transistors: a first inverter having first and second complementary FETS 102, 104; a second inverter having third and fourth complementary FETS 106, 108; and two access FETs 110, 112 (FIG. 2). The first and second inverters of the cell are cross-coupled to form a storage flip-flop, storing the one bit. The single CMOS SRAM cell is coupled to complementary bit lines 120, 122, and read/write word lines 130 in a multi-cell SRAM memory array through access transistors 110 and 112, respectively. Other configurations of a single CMOS RAM cell are possible, but all of these configurations use at least one CMOS inverter.

Integrated circuit (IC) layout is one of the processes in electronic design automation that leads to the manufacture of a multi-layered IC chip meeting performance, size, and manufacturability goals. IC layout is accomplished by a software program that transforms the circuits of an IC's logical circuit design to the patterns of conductor, semiconductor and dielectric materials, which comprise the components of each layer of the IC. A particular IC layout is based on a standard process and given technology node for which the various photolithographic, chemical, and mechanical process variables are known to produce a manufacturable IC having a satisfactory yield.

An IC layout is characterized by a set of ground rules, i.e., a set of predefined geometrical design rules used to verify that a layout of an IC should produce a manufacturable layout using a standard process. One such ground rule, for example, a spacing rule, can specify a minimum distance between two adjacent components. As seen from the discussion of technology nodes above, a spacing rule will necessarily reflect a given CMOS technology node.

Further scaling of SOI CMOS ICs to smaller node technologies will undoubtedly require structural changes to SOI CMOS component devices and changes to the ground rules for the layout of these component devices.

### SUMMARY

An aspect of an embodiment of the invention provides for a high circuit density, when the circuitry of an SOI CMOS IC includes a CMOS inverter including an asymmetric p-FET, an asymmetric n-FET, and a butted junction. The density of the circuitry using the asymmetric butted junction CMOS inverter of an exemplary embodiment of the invention is further increased by forming drain regions of the asymmetric p-FET and asymmetric n-FET, which are shorter than their corresponding source regions.

In view of the foregoing, an exemplary embodiment of the invention disclosed herein provides a semiconductor device comprising: an asymmetric p-channel field effect transistor (p-FET), formed on a silicon-on-insulator (SOI) substrate, that includes a halo implant on only a source side of the p-FET; an asymmetric n-channel FET (n-FET), formed on the SOI substrate, that includes a halo implant on only a source side of the n-FET; and a butted junction comprising an area of said SOI substrate where a drain region of the asymmetric n-FET and a drain region of the asymmetric p-FET are in direct physical contact.

In another embodiment of the invention, the semiconductor device is characterized by the drain region of the asymmetric p-FET being shorter than a source region of the asymmetric p-FET, and the drain region of the asymmetric n-FET being shorter than a source region of the asymmetric n-FET.

In yet another embodiment of the invention, the semiconductor device is characterized by the drain region of the asymmetric p-FET and the drain region of the asymmetric n-FET forming a common drain electrode.

In yet another embodiment of the invention, the semiconductor device is characterized by a gate of the asymmetric p-FET and a gate of the asymmetric n-FET being connected by a common electrical input.

In yet another embodiment of the invention, the semiconductor device is characterized by gate-to-gate spacing between the asymmetric p-FET and the asymmetric n-FET equaling a sum of lengths for the drain region of the asymmetric p-FET, and the drain region of the asymmetric n-FET.

In yet another embodiment of the invention, the semiconductor device is characterized by the gate-to-gate spacing being less than a sum of lengths for the source region of the asymmetric p-FET and the source region for the asymmetric n-FET.

In yet another embodiment of the invention, the semiconductor device is characterized by the silicon-on-insulator comprising: a substrate; an insulator layer formed on the substrate; and a top semiconductor layer, formed on the insulator layer, that includes shallow trench isolation (STI) regions and a semiconductor region.

In yet another embodiment of the invention, an exemplary embodiment of the invention disclosed herein provides a semiconductor device comprising: an asymmetric p-channel field effect transistor (p-FET), formed on a silicon-on-insulator (SOI) substrate, that includes a halo implant on only a source side of the p-FET; an asymmetric n-channel FET (n-FET), formed on the SOI substrate, that includes a halo implant on only a source side of the n-FET; and a butted junction comprising an area of said SOI substrate where a drain region of the asymmetric n-FET and a drain region of the asymmetric p-FET are in direct physical contact, in which the drain region of the asymmetric p-FET is shorter than a source region of the asymmetric p-FET, and in which the drain region of the asymmetric n-FET is shorter than a source region of the asymmetric n-FET.

In yet another embodiment of the invention, the semiconductor device is characterized by the drain region of the asymmetric p-FET and the drain region of the asymmetric n-FET forming a common drain electrode.

In yet another embodiment of the invention, the semiconductor device is characterized by a gate of the asymmetric p-FET and a gate of the asymmetric n-FET being connected by a common electrical input.

In yet another embodiment of the invention, the semiconductor device is characterized by gate-to-gate spacing between the asymmetric p-FET and the asymmetric n-FET equaling a sum of lengths for the drain region of the asymmetric p-FET and the drain region of the asymmetric n-FET.

In yet another embodiment of the invention, the semiconductor device is characterized by the gate-to-gate spacing being less than a sum of lengths for the source region of the asymmetric p-FET and the source region for the asymmetric n-FET.

In view of the foregoing, an exemplary embodiment of the invention disclosed herein provides a method of manufacturing a semiconductor device comprising: forming a first field effect transistor (FET) and a second FET on a silicon-on-insulator (SOI) substrate, the first FET being of a complementary conduction-type to the second FET, in which the forming of the first FET and the second FET comprises: forming a first gate of the first FET and a second gate of the second FET on the SOI substrate, in which a first channel region of the first FET is located beneath the first gate and a second channel region of the second FET is located beneath the second gate; forming a butted junction that physically contacts a first drain region of the first FET and a second drain region of the second FET, the butted junction being disposed medially to the first channel region and the second channel region; forming a first source region of the first FET lateral to the first channel region and a second source region of the second FET lateral to the second channel region; forming a second ion absorbing structure over the second FET; implanting a first halo implant on only the first source side of the first channel region of the first FET at an angle between a vertical axis and a horizontal axis extending from the butted junction to the first source region, to form a first asymmetric FET; removing the second ion absorbing structure; forming a first ion absorbing structure over the first FET; and forming a second halo implant on only the second source side of the second channel region of the second FET at an angle between the vertical axis and a horizontal axis extending from the butted junction to the second source region, to form a second asymmetric FET.

In yet another embodiment of the invention, the method of manufacturing a semiconductor device further comprising removing the first ion absorbing structure.

In yet another embodiment of the invention, the method of manufacturing being characterized by in the forming of the first source region and the second source region, the first source region and the second source region are formed such that the first drain region is shorter than the first source region and the second drain region is shorter than the second source region.

In yet another embodiment of the invention, the method of manufacturing being characterized by each of the drain regions of the first FET and the second FET forming a common drain electrode.

In yet another embodiment of the invention, the method of manufacturing further comprising forming conductive pathways to the first gate of the first asymmetric FET and the second gate of the second asymmetric FET, the conductive pathways sharing a common electrical input.

In yet another embodiment of the invention, the method of manufacturing being characterized by gate-to-gate spacing between the first asymmetric FET and the second asymmetric FET equaling a sum of lengths for the drain region of the first asymmetric FET and the drain region of the second asymmetric FET; and the gate-to-gate spacing being less than a sum of lengths for the source region of the first asymmetric FET and the source region for the second asymmetric FET.

In view of the foregoing, an exemplary embodiment of the invention disclosed herein provides a computer program product for displaying a layout of a semiconductor device, the computer program product comprising: a computer readable storage medium having computer readable program code embodied therewith, the computer readable program code comprising: computer readable program code configured to: apply a first ground rule for gate-to-gate spacing to a first portion of the layout display, corresponding to a first portion of a silicon-on-insulator (SOI) substrate layer that includes a pair of adjacent FETs formed on the SOI substrate layer, according to a given technology node, the pair of adjacent FETs being separated by a shallow isolating trench, and each of the pair of adjacent FETs having a gate formed on the SOI substrate; apply a second ground rule for gate-to-gate spacing to a second portion of the layout display, corresponding to a second portion of the SOI substrate layer that includes an asymmetric butted junction complementary metal oxide semiconductor (CMOS) inverter formed on the SOI substrate layer, the asymmetric butted junction CMOS inverter comprising: an asymmetric p-channel field effect transistor (p-FET) including: a gate; and a halo implant that is formed on only a source side of the asymmetric p-FET; an asymmetric n-channel FET (n-FET) including: a gate; and a halo implant that is formed on only a source side of the asymmetric n-FET; and a butted junction comprising an area of said SOI substrate where a drain region of the asymmetric p-FET and a drain region of the asymmetric n-FET are in direct physical contact; and display the layout using the first ground rule for gate-to-gate spacing of the first portion of the layout display according to the given technology node, and using the second ground rule for gate-to-gate spacing of the second portion of the layout display, wherein the gate-to-gate spacing of the second ground rule is less than that of the gate-to-gate spacing of the first ground rule.

In yet another embodiment of the invention, the computer program product for displaying a layout of a semiconductor device being characterized by the drain region of the asymmetric p-FET being shorter than a source region of the asymmetric p-FET, and the drain region of the asymmetric n-FET being shorter than a source region of the asymmetric n-FET.

### BRIEF DESCRIPTION OF THE DRAWINGS

The exemplary embodiments of the invention will be better understood from the following detailed description with reference to the drawings, which are not necessarily drawing to scale and in which:

FIG. 1 illustrates a block diagram of a prior art silicon-on-insulator (SOI) field effect transistor (FET) with symmetric halo implants and surrounding shallow isolation trenches;

FIG. 2 illustrates a block diagram of a prior art six transistor static random access memory (SRAM) cell including two complementary metal oxide semiconductor (CMOS) inverters;

FIG. 3 illustrates a cross section of a block diagram of an asymmetric butted junction CMOS inverter formed on an SOI substrate in an exemplary embodiment of the invention;

FIGS. 4A and 4B illustrate, respectively, the implantation of a first halo implant on only the source side of a channel region of one of the complementary SOI FETs of the asymmetric butted junction CMOS inverter, and the implantation of a second halo implant on only the source side of a channel region of the other one of the complementary SOI FETs of the asymmetric butted junction CMOS inverter in an exemplary embodiment of the invention;

FIG. 5 illustrates a flow diagram for a method of manufacturing the high density, butted junction CMOS inverter formed on an SOI substrate in an exemplary embodiment of the invention;

FIG. 6 illustrates a flow chart of a computer program product for displaying a layout of a semiconductor device in an exemplary embodiment of the invention;

FIG. 7 illustrates a block diagram of an electronic display of a CMOS integrated circuit, i.e., a six transistor (6T) SRAM cell, showing a smaller gate-to-gate spacing for the high density, asymmetric, butted junction CMOS inverter, when compared to gate-to-gate spacing of two adjacent FETS, i.e., the two access transistors of the 6T SRAM cell, of a given technology node in an exemplary embodiment of the invention; and

FIG. 8 illustrates a block diagram of a representative hardware environment for practicing exemplary embodiments of an aspect of the invention.

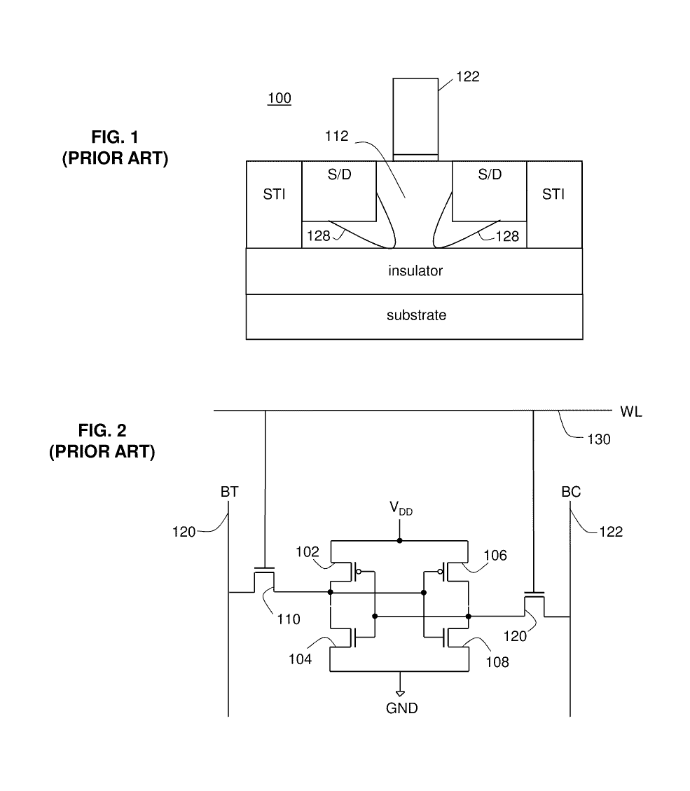

### DETAILED DESCRIPTION

The exemplary embodiments of the invention and the various features and advantageous details thereof are explained more fully with reference to the non-limiting exemplary embodiments that are illustrated in the accompanying drawings and detailed in the following description. It should be noted that the features illustrated in the drawings are not necessarily drawn to scale. Descriptions of well-known materials, components, and processing techniques are omitted so as to not unnecessarily obscure the exemplary embodiments of the invention. The examples used herein are intended to merely facilitate an understanding of ways in which the exemplary embodiments of the invention may be practiced and to further enable those of skill in the art to practice the exemplary embodiments of the invention. Accordingly, the examples should not be construed as limiting the scope of the exemplary embodiments of the invention.

As stated above, scaling of silicon-on-insulator (SOI) CMOS ICs to smaller technology nodes will require structural changes to SOI CMOS components.

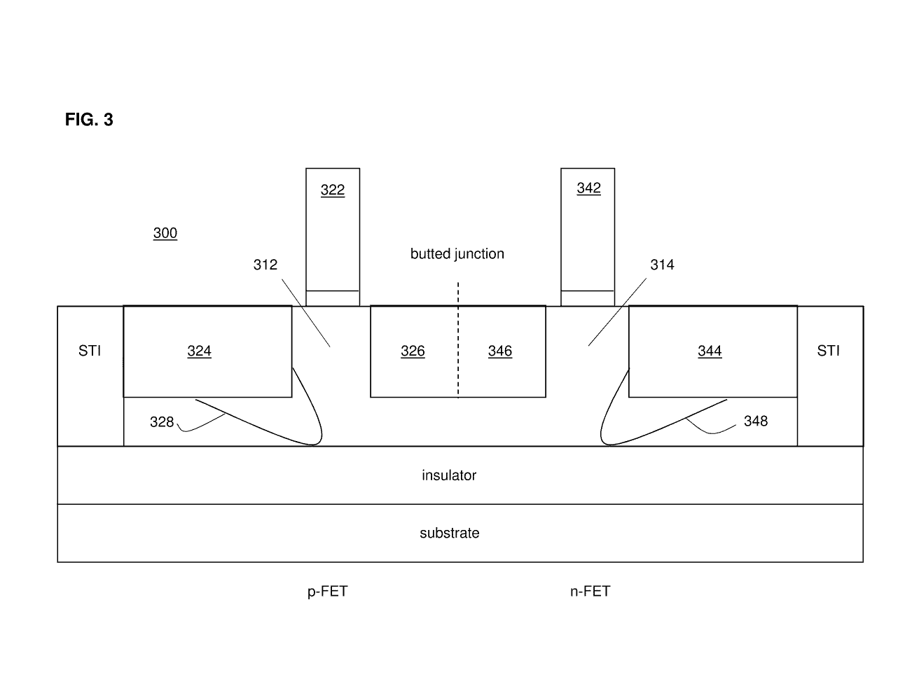

FIG. 3 illustrates a cross section of an SOI CMOS inverter 300, which may include an asymmetric p-FET and an asymmetric n-FET, and a butted junction, to provide higher circuit density in an exemplary embodiment of the invention. The asymmetric p-FET may include a gate stack including a gate 322 formed on the SOI substrate, a source region 324, and a drain region 326. The source region 324 of the asymmetric p-FET may be separated from the drain region 326 by a channel region 312 located beneath the gate 322. In an exemplary embodiment of the invention, a halo implant 328 may be asymmetrically implanted on only the source side of the channel region 312 of the asymmetric p-FET by an angled implantation process well known in the art.

The asymmetric n-FET of the SOI CMOS inverter 300 of FIG. 3 may include a gate stack including a gate 342 formed on the SOI substrate, a source region 344, and a drain region 346. The source region 344 may be separated from the drain region 346 by a channel region 314. In an exemplary embodiment of the invention, a halo implant 348 is asymmetrically implanted on only the source side of the channel region 314 of the asymmetric n-FET by the angled implantation process.

The asymmetric p-FET and asymmetric n-FET of the SOI CMOS inverter 300 may share a butted junction at the interface of the p-FET's drain region 326 and the n-FET's drain 346 in an exemplary embodiment of the invention. At the butted junction, the p-FET's drain region 326 and the n-FET's drain region 346 may be in direct physical contact without an isolation region between them, and may form a common drain electrode that provides electrical contact for output of the SOI CMOS inverter 300. FIG. 3 discloses a dotted line that indicates the imaginary interface between the p-FET drain region 326 and the n-FET drain region 346, which together form the common drain electrode.

In an exemplary embodiment of the invention, when compared to the length of the p-FET's source region 324, the length of the p-FET's drain region 326 may be of a lesser length. Similarly, when compared to the length of the n-FET's source region 344, the length of the n-FET's drain region 346 may also be of a lesser length.

In a conventional CMOS inverter, using a technology node of 250 nm or less, the p-FET and n-FET are electrically isolated, one from the other, by a shallow trench filled with a dielectric, i.e., shallow trench isolation (STI). Thus, in a conventional CMOS inverter using STI between the p-FET and the n-FET, the gate stack of the p-FET is separated from the gate stack of the n-FET by a distance equal to the sum of the length of the drain region of the p-FET, the length of the shallow isolation trench, and the length of the drain region of the n-FET.

Shallow trench isolation can also electrically isolate an asymmetric p-FET and asymmetric n-FET used in a CMOS inverter. Although the asymmetric p-FET and asymmetric n-FET may include an asymmetric halo implant, the asymmetric halo implant does not affect the distance between the gate stacks of these asymmetric FETs. Furthermore, the length of the source region and the length of the drain region of each of these asymmetric FETs in a conventional CMOS inverter of a given technology node are equal. Thus, the gate-to-gate spacing between the gate stacks of, for example, a non-butted junction CMOS inverter using asymmetric FETs of a given technology node includes the length of the drain region (which equals that of the source region) of the p-FET, the length of the shallow isolation trench, and the length of the drain region (which equals that of the source region) of the n-FET. Similarly, adjacent asymmetric FETs, used in any other CMOS circuit, will also possess a gate-to-gate spacing between gate stacks that includes a length of a source/drain region of a first FET, a length of a shallow isolation trench, and a length of a source/drain region for a second FET.

For a given node technology, the asymmetric butted junction SOI CMOS inverter 300 of an exemplary embodiment of the invention may offer a further reduction of scale for gate-to-gate spacing by implementing a butted drain junction, thus eliminating a shallow isolation trench between the two asymmetric FETs, and by reducing the length of the drain regions 326, 346 in comparison to the corresponding source regions 324, 344. In a given node technology, this reduction of gate-to-gate spacing for the asymmetric, butted junction SOI CMOS inverter of the invention may be used in conjunction with other circuits in a SOI CMOS device, for example, access transistors of a six transistor SRAM memory cell, to increase the overall circuit density. As will be discussed in detail below, reducing the length of the drain regions in comparison to the source regions facilitates the implantation of asymmetric halo implants in the p-FET and n-FET during manufacture of the asymmetric, butted junction SOI CMOS inverter of an exemplary embodiment of the invention.

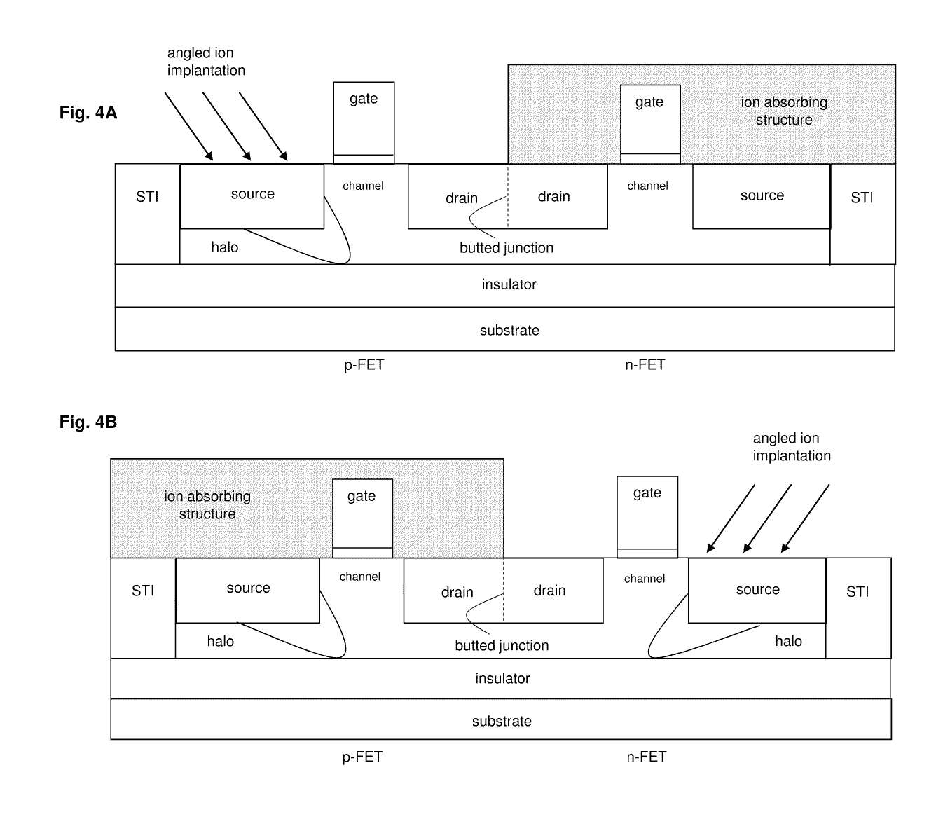

FIGS. 4A and 4B illustrate a method for manufacturing the high density, butted junction SOI CMOS inverter of an exemplary embodiment of the invention. In processes well known in the art, two complementary conduction-type FETs may be formed on an SOI substrate. A gate, which forms part of a gate stack, may be formed for each of the complementary FETs on the SOI substrate and underneath each gate of the complementary FETs may be formed a corresponding channel region. In an exemplary embodiment of the invention, a butted junction may be formed by the drain regions of each of the two complementary FETs, where the drain regions may be disposed medially to the two channel regions of the complementary FETs. A source region may be formed for each of the complementary FETs, each source region being formed laterally to each FET's channel region.

As in known in the art, performance of scaled FETs may be enhanced by an asymmetric angled ion implantation process for the implantation of halo implants on only the source sides of their channel regions. To implement the asymmetric angled ion implantation process for the high density, asymmetric, butted junction CMOS inverter of the invention, an ion absorbing structure may be formed over one of the two complementary FETs, for example, the n-FET illustrated in FIG. 4A. In an exemplary embodiment of the invention, a first angled ion implantation process, using an angle between the vertical axis and a horizontal axis extending from the butted junction to the exposed FET, i.e., the p-FET of FIG. 4A, may then implant a first halo on only the source side of the channel of the exposed FET. In this first angled ion implantation process, the gate stack of the FET shadows the drain of the FET from ion implantation, while the ion absorbing structure prevents ion implantation in the complementary FET of FIG. 4A in an exemplary embodiment of the invention. As illustrated in FIG. 4B, the ion absorbing structure may then be removed from over the n-FET of FIG. 4A and another ion absorbing structure may then be formed over the p-FET of FIG. 4B for a second angled ion implantation process in an exemplary embodiment of the invention. A second halo may then be implanted on only the source side of the channel of the FET, which had previously been covered by the first ion absorbing structure, i.e., the n-FET of FIG. 4B, by an angled implantation process at an angle between the vertical axis and a horizontal axis extending from the butted junction to the exposed FET, i.e., the n-FET of FIG. 4B, in an exemplary embodiment of the invention. The ion absorbing structure covering the p-FET of FIG. 4B may then be removed.

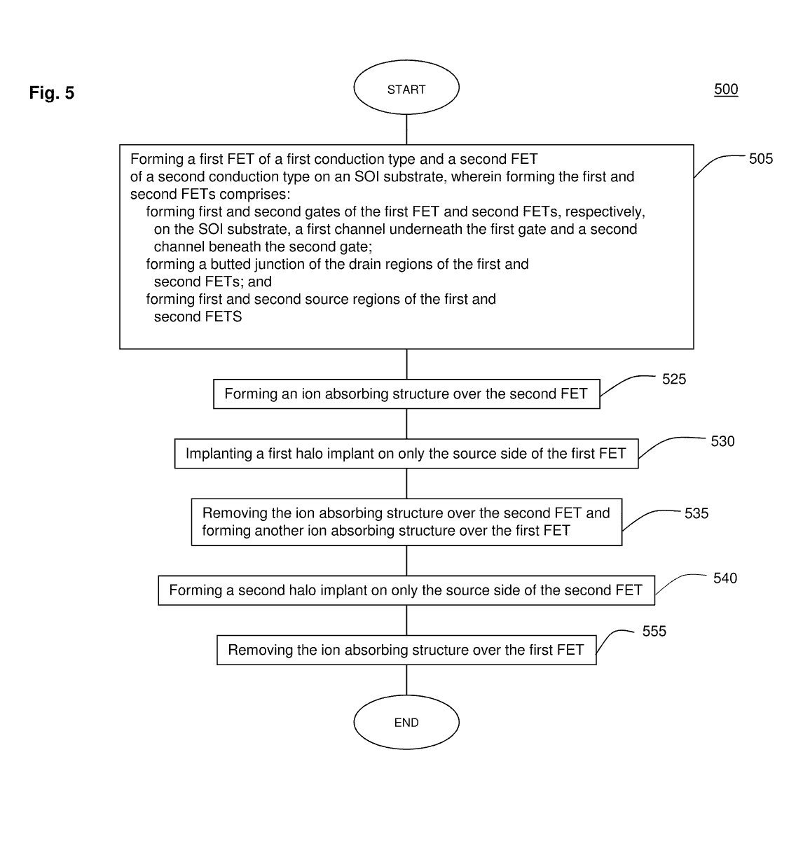

FIG. 5 illustrates a flow chart 500 of a method of manufacturing a high density, asymmetric, butted junction CMOS inverter of an exemplary embodiment of the invention. Initially, a first FET and a second FET may be formed on a substrate, in which the first FET and the second FET are of complementary conduction-types 505. Particularly, the forming of the first FET and the second FET may comprise: forming a first gate of the first FET and a second gate of the second FET, in which a first channel region of the first FET is located beneath the first gate and a second channel region of the second FET is located beneath the second gate; forming a butted junction that physically contacts a first drain region of the first FET and a second drain region of the second FET, where the butted junction is disposed medially to the first channel region and the second channel region; and forming a first source region of the first FET lateral to the first channel region and a second source region of the second FET lateral to the second channel region in an exemplary embodiment of the invention 505. An ion absorbing structure may be formed over the second FET in an exemplary embodiment of the invention 525. A first halo implant may be implanted on only a first source side of the first channel region of the first FET at an angle between the vertical axis and a horizontal axis extending from said butted junction to the first source region, to form a first asymmetric FET in an exemplary embodiment of the invention 530. The ion absorbing structure may be removed from over the second FET and a second ion absorbing structure may be formed over the first FET 535. In an exemplary embodiment of the invention, a second halo implant may be implanted on only a second source side of the second channel region of the second FET at an angle between the vertical axis and a horizontal axis extending from said butted junction to the second source region, to form a second asymmetric FET 540. The second ion absorbing structure may then be removed from over the first asymmetric FET 555.

As described above with regard to the structure of the high density, asymmetric CMOS inverter of an exemplary embodiment of the invention, when compared to the lengths of the source regions of each of the complementary FETS, the lengths of the drain regions, including both semiconductor drain and drain electrode, may be of a lesser length. In addition, the drain electrodes of each of the complementary FETS may form a common drain electrode.

In an exemplary embodiment of the invention, conductive pathways may be formed to each of the gates of the two asymmetric complementary FETs and these conductive pathways may share a common electrical input. It may be noted that the gate-to-gate spacing of the two asymmetric complementary FETs of an exemplary embodiment of the invention equals a sum of lengths for the semiconductor drain of one of the two asymmetric complementary FETs, the common electrode, and for the semiconductor drain of the other of the two asymmetric complementary FETs. In addition, a sum of the lengths of the two drain regions are of a lesser length than the sum of the lengths of the two source regions in an exemplary embodiment of the invention.

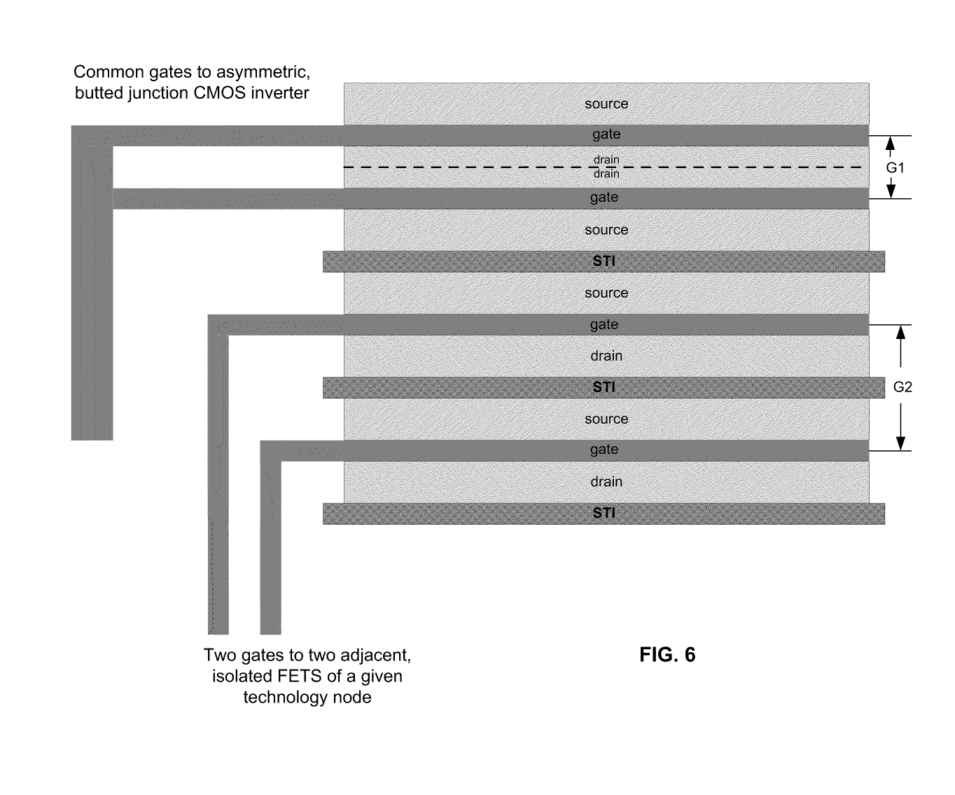

FIG. 6 illustrates an electronic display of a layout of a CMOS integrated circuit, for example, a six transistor SRAM cell, that includes the high density, asymmetric, butted junction CMOS inverter and two adjacent FETS of a given technology node, which may correspond to the access transistors of the six transistor SRAM cell in an exemplary embodiment of the invention. The two asymmetric complementary FETs of the CMOS inverter of the invention may exhibit a smaller gate-to-gate spacing, i.e., gate pitch=G1, than that shown by the two adjacent FETS of the given technology node, i.e., gate pitch=G2, where G1<G2. The two adjacent FETs of the given technology node, which is less than that of 250 nm, are electrically isolated one from the other by a shallow isolation trench and do not posses drain regions that are comparatively shorter than their source regions as do the complementary FETs of the high density, asymmetric, butted junction CMOS inverter. Referring to FIG. 6, for a given technology node, the electronic layout display may apply a first ground rule for gate-to-gate spacing to a portion of the layout display that includes, for example, the two adjacent isolated access FETs of a six transistor SRAM cell, while applying a second ground rule for the gate-to-gate spacing for that portion of the layout display that includes the high density, asymmetric, butted junction CMOS inverter in an exemplary embodiment of the invention.

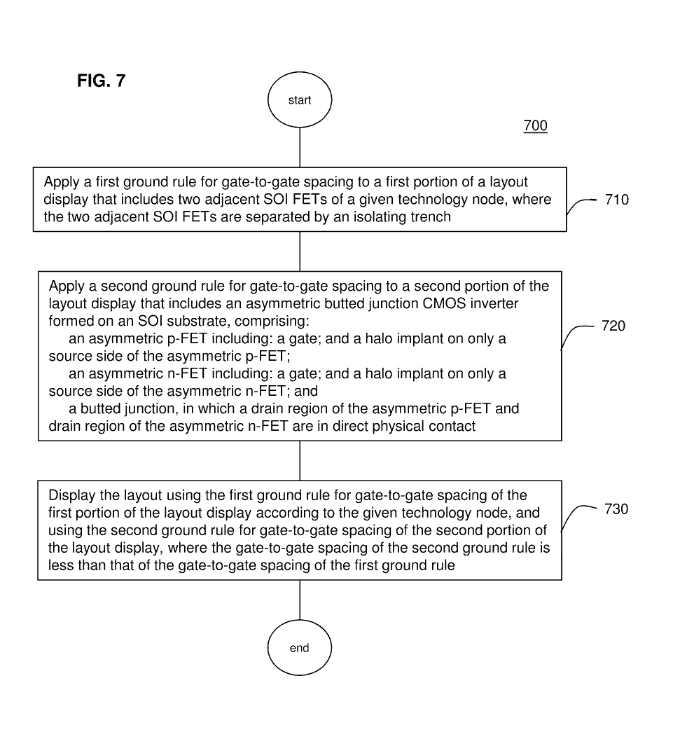

FIG. 7 illustrates a flow diagram 700 for a computer program product, which includes a computer readable storage medium having computer readable code configured to electronically display a layout of a CMOS semiconductor device according to a given technology node, in which the layout is characterized by a set of ground rules, i.e., a set of predefined geometrical design rules used to verify that a layout of the CMOS semiconductor device should produce a manufacturable layout. In an exemplary embodiment of the invention, the computer readable code may allow a first ground rule for gate-to-gate spacing to be applied to a first portion of the electronic layout display, corresponding to a first portion of a substrate layer of the semiconductor CMOS device, upon which is formed a pair of adjacent FETs according to a given technology node 710. It is anticipated that the technology node may be less than 45 nm in an exemplary embodiment of the invention. Each of the pair of adjacent FETs may have a gate formed on the substrate layer and may be electrically isolated from the other member of the pair by shallow trench isolation in an exemplary embodiment of the invention.

The computer readable code may also allow a second ground rule for gate-to-gate spacing to be applied to a second portion of the electronic layout display, corresponding to a second portion of the substrate layer, upon which is formed the asymmetric butted junction CMOS inverter of an exemplary embodiment of the invention 720. The asymmetric butted junction CMOS inverter displayed by the layout may comprise: an asymmetric p-FET including a gate and a halo implant that is formed on only a source side of the asymmetric p-FET; an asymmetric n-FET including a gate and a halo implant that is formed on only a source side of the asymmetric n-FET; and a butted junction comprising an area of said SOI substrate where a drain region of the asymmetric p-FET and a drain region of the asymmetric n-FET are in direct physical contact in an exemplary embodiment of the invention.

As indicated in 730 of FIG. 7, the computer readable code may electronically display the layout using the first ground rule for gate-to-gate spacing of the first portion of the layout display including the adjacent pair of FETs according to the given technology node, while using the second ground rule for gate-to-gate spacing of the second portion of the layout display including the asymmetric butted junction CMOS inverter, wherein the gate-to-gate spacing of the second ground rule is less than that of the gate-to-gate spacing of the first ground rule in an exemplary embodiment of the invention. It is also noted that the second ground rule may encompass a structural constraint of the asymmetric butted junction CMOS inverter, which requires the drain region of the asymmetric p-FET to be shorter than the source region of the asymmetric p-FET and the drain region of the asymmetric n-FET to be shorter than the source region of the asymmetric n-FET.

Aspects of the present invention may take the form of a computer program product embodied in one or more computer readable medium(s) having computer readable program code embodied thereon. Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

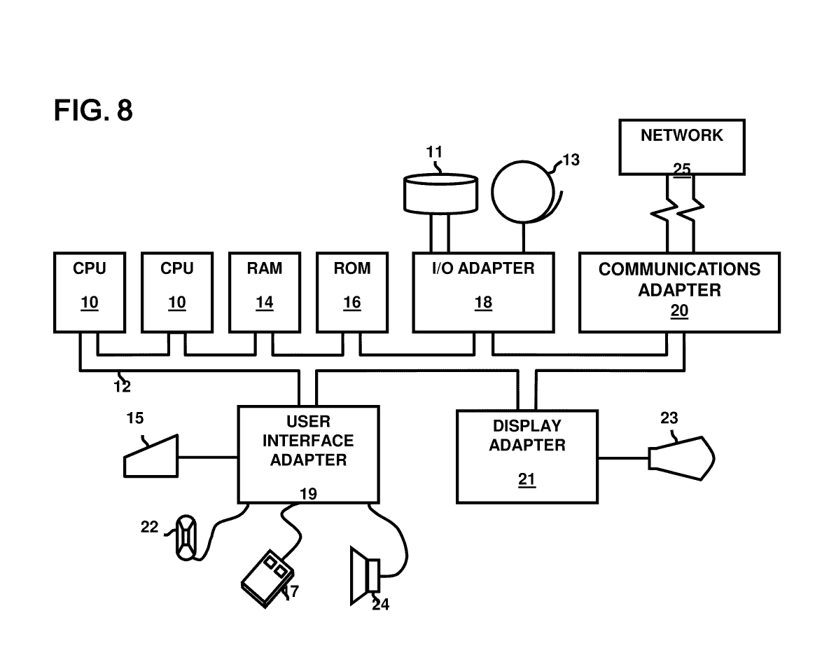

A representative hardware environment for practicing the embodiments of the invention is depicted in FIG. 8. This schematic drawing illustrates a hardware configuration of an information handling/computer system in accordance with the embodiments of the invention. The system comprises at least one processor or central processing unit (CPU) 10. The CPUs 10 are interconnected via system bus 12 to various devices such as a random access memory (RAM) 14, read-only memory (ROM) 16, and an input/output (I/O) adapter 18. The I/O adapter 18 can connect to peripheral devices, such as disk units 11 and tape drives 13, or other program storage devices that are readable by the system. The system can read the inventive instructions on the program storage devices and follow these instructions to execute the methodology of the embodiments of the invention. The system further includes a user interface adapter 19 that connects a keyboard 15, mouse 17, speaker 24, microphone 22, and/or other user interface devices such as a touch screen device (not shown) to the bus 12 to gather user input. Additionally, a communication adapter 20 connects the bus 12 to a data processing network 25, and a display adapter 21 connects the bus 12 to a display device 23 which may be embodied as an output device such as a monitor, printer, or transmitter, for example.

What is claimed is:

1. A semiconductor device comprising:
a silicon-on-insulator (SOI) substrate;
an asymmetric p-channel field effect transistor (p-FET) formed on said SOI substrate, said p-FET including a halo implant on only a source side of said p-FET;
an asymmetric n-channel FET (n-FET) formed on said SOI substrate, said n-FET including a halo implant on only a source side of said n-FET; and
a butted junction comprising an area of said SOI substrate where a drain region of said asymmetric n-FET and a drain region of said asymmetric p-FET are in direct physical contact.

2. The semiconductor device of claim 1, wherein said drain region of said asymmetric p-FET is shorter than a source region of said asymmetric p-FET, and wherein said drain region of said asymmetric n-FET is shorter than a source region of said asymmetric n-FET.

3. The semiconductor device of claim 2, wherein said drain regions for said asymmetric p-FET and said asymmetric n-FET form a common drain electrode.

4. The semiconductor device of claim 1, wherein a gate of said asymmetric p-FET and a gate of said asymmetric n-FET are connected by a common electrical input.

5. The semiconductor device of claim 3, wherein:
a gate-to-gate spacing between said asymmetric p-FET and said asymmetric n-FET equals a sum of lengths for said drain region of said asymmetric p-FET, and said drain region of said asymmetric n-FET.

6. The semiconductor device of claim 5, wherein said gate-to-gate spacing is less than a sum of lengths for said source region of said asymmetric p-FET and said source region for said asymmetric n-FET.

7. The semiconductor device of claim 1, wherein said SOI substrate comprises:
a substrate;
an insulator layer formed on said substrate; and
a top semiconductor layer, formed on said insulator layer, that includes shallow trench isolation (STI) regions and a semiconductor region.

8. A semiconductor device comprising:
a silicon-on-insulator (SOI) substrate;
an asymmetric p-channel field effect transistor (p-FET) formed on said SOI substrate, said p-FET including a halo implant on only a source side of said p-FET;
an asymmetric n-channel FET (n-FET) formed on said SOI substrate, said n-FET including a halo implant on only a source side of said n-FET; and
a butted junction comprising an area of said SOI substrate where a drain region of said asymmetric n-FET and a drain region of said asymmetric p-FET are in direct physical contact, wherein said drain region of said asymmetric p-FET is shorter than a source region of said asymmetric p-FET, and wherein said drain region of said asymmetric n-FET is shorter than a source region of said asymmetric n-FET.

9. The semiconductor device of claim 8, wherein said drain regions for said asymmetric p-FET and said asymmetric n-FET form a common drain electrode.

10. The semiconductor device of claim 9, wherein a gate of said asymmetric p-FET and a gate of said asymmetric n-FET are connected by a common electrical input.

11. The semiconductor device of claim 10, wherein a gate-to-gate spacing between said asymmetric p-FET and said asymmetric n-FET equals a sum of lengths for said drain region of said asymmetric p-FET, and said drain region of said asymmetric n-FET.

12. The semiconductor device of claim 11, wherein said gate-to-gate spacing is less than a sum of lengths for said source region of said asymmetric p-FET and said source region for said asymmetric n-FET.

13. A method of manufacturing a semiconductor device comprising:
forming a first field effect transistor (FET) and a second FET on a silicon-on-insulator (SOI) substrate, said first FET being of a complementary conduction-type to said second FET, wherein said forming of said first FET and said second FET comprises:
forming a first gate of said first FET and a second gate of said second FET on said SOI substrate, wherein a first channel region of said first FET is located beneath said first gate and a second channel region of said second FET is located beneath said second gate;
forming a butted junction that physically contacts a first drain region of said first FET and a second drain region of said second FET, said butted junction being disposed medially to said first channel region and said second channel region;
forming a first source region of said first FET lateral to said first channel region and a second source region of said second FET lateral to said second channel region;
forming an ion absorbing structure over said second FET;
implanting a first halo implant on only said first source side of said first channel region of said first FET at an angle between a vertical axis and a horizontal axis extending from said butted junction to said first source region, to form a first asymmetric FET;
removing said ion absorbing structure;
forming another ion absorbing structure over said first FET; and
forming a second halo implant on only said second source side of said second channel region of said second FET at an angle between said vertical axis and a horizontal axis extending from said butted junction to said second source region, to form a second asymmetric FET.

14. The method of claim 13 further comprising removing said another ion absorbing structure.

15. The method of claim 13, wherein in said forming of said first source region and said second source region, said first source region and said second source region are formed such that said first drain region is shorter than said first source region and said second drain region is shorter than said second source region.

16. The method of claim 15, further comprising forming a common drain electrode from said drain region of said first FET and said drain region of said second FET.

17. The method of claim 13 further comprising forming conductive pathways to said first gate of said first asymmetric FET and said second gate of said second asymmetric FET, said conductive pathways sharing a common electrical input.

18. The method of claim 16, wherein:
a gate-to-gate spacing between said first asymmetric FET and said second asymmetric FET equals a sum of lengths for said drain region of said first asymmetric FET, and said drain region of said second asymmetric FET; and
said gate-to-gate spacing is less than a sum of lengths for said source region of said first asymmetric FET and said source region for said second asymmetric FET.

19. A computer program product for displaying a layout of a semiconductor device, the computer program product comprising:
a computer readable storage medium having computer readable program code embodied therewith, the computer readable program code comprising: computer readable program code configured to:
apply a first ground rule for gate-to-gate spacing to a first portion of a layout display, corresponding to a first portion of a silicon-on-insulator (SOI) substrate layer that includes a pair of adjacent FETs formed on said SOI substrate layer, according to a given technology node, said pair of adjacent FETs being separated by a shallow isolating trench, and each of said pair of adjacent FETs having a gate formed on said SOI substrate;
apply a second ground rule for gate-to-gate spacing to a second portion of said layout display, corresponding to a second portion of said SOI substrate layer that includes an asymmetric butted junction complementary metal oxide semiconductor (CMOS) inverter formed on said SOI substrate layer, said asymmetric butted junction CMOS inverter comprising:
an asymmetric p-channel field effect transistor (p-FET) including:
a gate; and a halo implant that is formed on only a source side of said asymmetric p-FET;
an asymmetric n-channel FET (n-FET) including: a gate; and a halo implant that is formed on only a source side of said asymmetric n-FET; and
a butted junction comprising an area of said SOI substrate where a drain region of said asymmetric p-FET and a drain region of said asymmetric n-FET are in direct physical contact; and
display said layout using said first ground rule for gate-to-gate spacing of said first portion of said layout display according to said given technology node, and using said second ground rule for gate-to-gate spacing of said second portion of said layout display, wherein said gate-to-gate spacing of said second ground rule is less than that of said gate-to-gate spacing of said first ground rule.

20. The computer program product of claim 19, wherein said drain region of said asymmetric p-FET is shorter than a source region of said asymmetric p-FET, and said drain region of said asymmetric n-FET is shorter than a source region of said asymmetric n-FET.
